(19) United States
(12) Patent Application Publication
(10) Pub. No.: US 2012/0018827 A1
(43) Pub. Date: Jan. 26, 2012

(54) MULTI-SENSOR INTEGRATED CIRCUIT DEVICE

(75) Inventors: Nevzat Akin Kestelli, San Jose, CA (US); David Skurnik, Kirkland, WA (US)

(73) Assignee: MAXIM INTEGRATED PRODUCTS, INC., Sunnyvale, CA (US)

(21) Appl. No.: 13/187,153

(22) Filed: Jul. 20, 2011

Related U.S. Application Data
(60) Provisional application No. 61/367,344, filed on Jul. 23, 2010.

(51) Int. Cl. H01L 29/82; H01L 29/66

(52) U.S. Cl. 257/427; 257/414; 257/E29.323; 257/E29.166

(57) ABSTRACT

A multiple sensor-types integrated circuit device includes a semiconductor die including a first sensor type and a second sensor type formed thereon, an electrically insulating package enclosing the semiconductor die and a plurality of electrically conductive leads coupled to the semiconductor die and extending from the package. By way of example and not limitation, a multiple sensor-types integrated circuit die includes a semiconductor substrate of a first polarity, a plurality of regions of the first polarity formed in the substrate, where the plurality of regions are relatively more heavily doped than the substrate, multiple wells formed in the substrate, and a covering layer formed over the substrate.

### RELATED APPLICATIONS

This application claims priority of U.S. Provisional Application Ser. No. 61/367,344, filed Jul. 23, 2010, and entitled “Multi-Sensor Integrated Circuit Device”, by these same inventors. This application incorporates U.S. Provisional Application Ser. No. 61/367,344 in its entirety by reference.

### FIELD OF THE INVENTION

This invention relates to sensors for electronic devices. More specifically, this invention relates to a multi-sensor integrated circuit device.

### BACKGROUND OF THE INVENTION

A sensor is a device which receives and responds to a signal or stimulus. Here, the term “stimulus” means a property or a quantity that needs to be converted into electrical form. Hence, sensor can be defined as a device which receives a signal and converts it into electrical form which can be further used for electronic devices. A sensor differs from a transducer in the way that a transducer converts one form of energy into other form whereas a sensor converts the received signal into electrical form only.

There are many types of sensors. For example, there are sensors which respond to light, motion, temperature, magnetic fields, gravity, humidity, vibration, acceleration, pressure, electrical fields, sound and other physical aspects of the ambient environment.

Sensors can be made from discrete components, or may be made as an integrated circuit device, such as the integrated circuit device 10 of FIG. 1. An integrated circuit device 10 typically includes an electrically insulating package 12 enclosing a semiconductor die 14 (shown in phantom) and a number of electrically conductive leads 16 coupled to the semiconductor die 14 and extending out of the package 12. The package 12 can be quite small, e.g. 2 mm×2 mm, and the semiconductor die 14 can be even smaller, e.g. 100 μm×100 μm.

Sensors that are formed as integrated circuit devices can be inexpensively mass-produced and are quite rugged. These factors, along with their small size, make them attractive for use in portable electronic devices such as laptop computers and cellular telephones.

Integrated circuit device sensors include light (“optical”) sensors, magnetic field (“magnetic”) sensors, temperature sensors, etc. These integrated circuit devices are often dedicated to only a specific sensing function. Because various sensor types have disparate manufacturing and environmental requirements, only one sensor type is provided per integrated circuit device.

FIG. 2 illustrates, in a conceptual form, a prior art die 14′ that includes a single sensor-type block 18, a control block 20 and a conditioning block 22. The single sensor-type can be, for example, a number of ambient light sensor (ALS) photodiode cells which comprise sensor block 18. In this example, control block 20 can control the interconnections between the photodiode cells, and the conditioning block 22 can “condition” the output signals of the photodiode cells. By “condition” it is meant that the outputs of the sensors are enhanced, combined or modified in some fashion before being output from the integrated circuit device 12. Conditioning can be analog and/or digital in nature. For example, amplification is a common form of analog conditioning and analog-to-digital conversion (ADC) is a common form of analog/digital conditioning.

FIGS. 3A and 3B illustrate a prior art ALS photodiode cell 24 which may form one cell of the sensor block 18, as noted above. FIG. 3A is a top plan view of the cell 24 and FIG. 3B is a cross-sectional view taken along line 3B-3B of FIG. 3A. The cell 24, in this example, includes an N-substrate 28, a first Pwell 30, a second Pwell 32, and a cover layer 34. The N-substrate typically comprises doped silicon, although other semiconductor materials can be used as will be appreciated by those of skill in the art. Also, the polarities of the substrate and the wells can be reversed. The cover layer 34 is translucent such that light L can penetrate through the cover layer 34 to the layers below. By “light” it is meant electromagnetic radiation typically ranging from the infrared (IR) through the ultraviolet (UV) spectrums which, of course, includes visible light. The depth of the penetration of the light L into the layers below cover layer 34 is dependent upon its wavelength, where longer wavelength light penetrates further. The cover layer 34 can serve as a filter to change the spectrum of the light L such that the cell 24 can be tuned to be sensitive to certain wavelengths of light more than others. The manufacture and use of ALS photodiode cells, such as ALS photodiode cell 24, is well known to those of skill in the art.

FIGS. 4A and 4B illustrate a Hall Effect magnetic sensor 36 which may form one cell, by way of non-limiting example, of the sensor block 18 of FIG. 1. FIG. 4A is a top plan view of the Hall Effect cell 36 and FIG. 4B is a cross-sectional view taken along line 4B-4B of FIG. 4A. The cell 36 includes an N-substrate 40, four N+ regions 42, 44, 46 and 48, and a cover layer 50. The N-substrate 40 is typically silicon, e.g. an N-doped silicon wafer, although other semiconductor materials can be used as will be appreciated by those of skill in the art. The cover layer 50 is typically opaque such that light L is substantially blocked from impinging on the layers below to avoid a potential interference with the proper functioning of the Hall Effect magnet sensor. For example, the cover layer 50 can be a metal layer such as aluminum. If, however, the die is packaged in an opaque package, the cover layer 50 does not need to be opaque and/or may be omitted. The manufacture and use of Hall Effect magnetic sensors, such as the Hall Effect cell 36, is well known to those of skill in the art. For a given magnetic sensor, an input current results in a known voltage in the absence of a magnetic field. When a magnetic field is present, an offset voltage is measured, as compared to the known voltage. The magnitude of the offset voltage is proportional to the magnetic field.

FIG. 5 illustrates a block 18′ of sensor cells formed as part of a semiconductor die 14″ in accordance with the prior art. While some of the cells are labeled “S” and some of the cells are labeled “DS” they are all of the same sensor type. For example, the S cells can be the photodiode cells illustrated in FIGS. 3A and 3B, while the DS cells are the same as the S cells with the exception that the covering layer is opaque rather than translucent. These are referred to as “dark cells” which can be used to detect noise and random fluctuations in the sensor block 18′. Therefore, the signals produced by the dark cells DS can be subtracted from the signals of the cells S (in, for example, a conditioning circuit) to produce an output signal with reduced noise levels.

As noted, while the various sensor types have features in common, they also have features which are quite disparate. For example, a photodiode cell must be exposed to light, while a Hall Effect cell is typically shielded from light. Therefore, the package for a light sensor is typically at least translucent (or is provided with a translucent window to the wavelengths of interest) and the package for a Hall Effect magnetic sensor is typically opaque. As such, the motivation for combining multiple sensor-types on a common die is not apparent in the prior art.

These and other limitations of the prior art will become apparent to those of skill in the art upon a reading of the following descriptions and a study of the several figures of the drawing.

### SUMMARY OF THE INVENTION

By way of example and not limitation, a multiple sensor-type integrated circuit device includes: a semiconductor die including a first sensor type and a second sensor type formed thereon; an electrically insulating package enclosing said semiconductor die; and a plurality of electrically conductive leads coupled to said semiconductor die and extending from said package.

In an embodiment, the first sensor type is an optical sensor and the second sensor type is a magnetic sensor. In an embodiment, the semiconductor die includes a block, further wherein the block comprises a plurality of cells. In some embodiments, each cell includes only of the optical sensor or the magnetic sensor. In other embodiments, each cell includes a multiple sensor-type sensor including the optical sensor and the magnetic sensor. In some embodiments, each cell further includes a translucent cover layer. In an embodiment, the device also include control circuitry coupled to the block, wherein the control circuitry comprises a processing algorithm configured to compensate for the effect of light impinging the magnetic sensor. In an embodiment, each cell further includes a cover layer, wherein the cover layer for at least one of the cells is opaque, and the covering layer for the remaining cells is translucent. In an embodiment, a magnetic sensor signal from the at lest one cell having the opaque cover layer is processed to determine a presence of a magnetic field. In an embodiment, the optical sensor in the at least one cell having the opaque cover layer is used to measure a dark current of the optical sensor. In an embodiment, each cell includes a cover layer, wherein the cover layer includes an opaque portion positioned over the magnetic sensor and a translucent portion positioned over the optical sensor.

In an embodiment, the first sensor type and the second sensor type are formed in a cell. In an embodiment, the first sensor type and the second sensor type are formed in a block having a plurality of cells. In an embodiment, the block is a first block and further including a second block of the first sensor type. In an embodiment, the first sensor type is formed in a first block and in a second block and wherein the second sensor type is formed in a third block. In an embodiment, the device further includes a conditioning block formed on the semiconductor die. In an embodiment, both the first sensor type and the second sensor type are coupled to the conditioning block. In an embodiment, the first sensor type and the second sensor type are coupled to the conditioning block by a multiplexer. In an embodiment, the conditioning block is a first conditioning block associated with the first sensor and further including a second conditioning block associated with the second sensor.

In an embodiment, the conditioning block includes an amplifier circuit having an input coupled to at least one of the first sensor type and the second sensor type. In an embodiment, the conditioning block further includes an analog-to-digital converter (ADC) having an input coupled to an output of the amplifier circuit. In an embodiment, the conditioning block further includes a digital signal processor (DSP) having an input coupled to an output of the ADC. In an embodiment, the conditioning block further includes a gain control coupled between an input and an output of the amplifier. In an embodiment, a control input of the gain control is coupled to the DSP. In an embodiment, the device further includes control circuitry coupled to at least one of the first sensor type and the second sensor type. In an embodiment, the integrated circuit device forms a part of an electronic device selected from the group consisting essentially of computers, telephones and hand-held electronic devices.

By way of example and not limitation, a multiple sensor-type integrated circuit die includes: a semiconductor substrate of a first polarity; a plurality of regions of the first polarity formed in the substrate, the plurality of regions being relatively more heavily doped than the substrate, wherein the plurality of regions comprise a first sensor type; a plurality of wells of a second polarity formed in the substrate, wherein the plurality of wells comprise a second sensor type different than the first sensor type; and a cover layer formed over the substrate.

In an embodiment, the semiconductor substrate is an N-substrate, the plurality of regions are N+ regions, and the plurality of wells are P wells. In an embodiment, the cover layer over the P wells is of a first type and the cover layer over the N+ regions is of a second type. In an embodiment, the cover layer of the first type is non-metallic and the cover layer of the second type is metallic. In an embodiment, the cover layer of the first type is translucent and the cover layer of the second type is opaque.

By way of example and not limitation, a multiple sensor-type integrated circuit die includes: a multiple sensor-type sensor block including a first type of sensor and a second type of sensor; and a conditioning block coupled to the multiple sensor-type sensor block to process a first sensor signal corresponding to the first type of sensor and a second signal corresponding to the second type of sensor.

In an embodiment, the first type of sensor includes an optical sensor and the second type of sensor includes a magnetic sensor, further wherein the conditioning block is configured to process both optical signals and magnetic signals sensed by the multiple sensor-type sensor block. In an embodiment, the die further includes a multiplexer coupled between the multiple sensor-type sensor block and the conditioning block. In an embodiment, the conditioning block includes an amplifier circuit having an input coupled to at least one of the first sensor type and the second sensor type. In an embodiment, the conditioning block further includes an analog-to-digital converter (ADC) having an input coupled to an output of the amplifier circuit. In an embodiment, the conditioning block further includes a digital signal processor (DSP) having an input coupled to an output of the ADC. In an embodiment, the conditioning block further includes a gain control coupled between an input and an output of the amplifier. In an embodiment, a control input of the gain control is coupled to the DSP. In an embodiment, the die further includes control circuitry coupled to at least one of the first sensor type and the second sensor type.

These and other embodiments and advantages and other features disclosed herein will become apparent to those of skill in the art upon a reading of the following descriptions and a study of the several figures of the drawing.

### BRIEF DESCRIPTION OF THE DRAWINGS

Several example embodiments will now be described with reference to the drawings, wherein like components are provided with like reference numerals. The example embodiments are intended to illustrate, but not to limit, the invention. The drawings include the following figures:

FIG. 1 illustrates a perspective view of an integrated circuit device.

FIG. 2 illustrates a single sensor type semiconductor die of the prior art.

FIG. 3A illustrates a top plan view of a photodiode cell of the prior art, which can be used as a light sensor.

FIG. 3B illustrates a cross-sectional view taken along line 3B-3B of FIG. 3A;

FIG. 4A illustrates a top plan view of a Hall Effect cell of the prior art, which can be used as a magnetic sensor.

FIG. 4B illustrates a cross-sectional view taken along line 4B-4B of FIG. 4A.

FIG. 5 illustrates an illustration of a sensor block of the prior art comprising a plurality of sensor cells of the same type.

FIG. 6 illustrates a multiple sensor-types semiconductor die.

FIG. 7 illustrates a multiple sensor-types block which forms at least a part of multiple sensor-types block in FIG. 6.

FIG. 8A illustrates a multiple sensor-types block having sensor cells of a first sensor cell type S1 and a second sensor cell type S2.

FIG. 8B illustrates a multiple sensor-types block having sensor cells of multiple sensor-types, such as the first sensor cell type S1 and the second sensor cell type S2.

FIG. 9 illustrates a block diagram of a plurality of sensor types having outputs multiplexed to a common conditioner.

FIG. 10A illustrates a top plan view of a first combination photodiode and Hall Effect sensor cell.

FIG. 10B illustrates a cross-sectional view taken along line 10B-10B of FIG. 10A.

FIG. 10C illustrates a cross-sectional view taken along line 10B-10B of FIG. 10A including a cover layer according to an embodiment.

FIG. 10D illustrates a cross-sectional view taken along line 10B-10B of FIG. 10A including a cover layer according to another embodiment.

FIG. 10E illustrates a cross-sectional view taken along line 10B-10B of FIG. 10A including a cover layer according to yet another embodiment.

FIG. 11A illustrates a top plan view of a second combination photodiode and Hall Effect sensor cell.

FIG. 11B illustrates a cross-sectional view taken along line 11B-11B of FIG. 11A including a cover layer according to an embodiment.

FIG. 11C illustrates a cross-sectional view taken along line 11B-11B of FIG. 11A including a cover layer according to another embodiment.

FIG. 11D illustrates a cross-sectional view taken along line 11B-11B of FIG. 11A including a cover layer according to yet another embodiment.

FIG. 12A illustrates a top plan view of a third combination photodiode and Hall Effect sensor cell.

FIG. 12B illustrates a cross-sectional view taken along line 12B-12B of FIG. 12A including a cover layer according to an embodiment.

FIG. 12C illustrates a cross-sectional view taken along line 12B-12B of FIG. 12A including a cover layer according to another embodiment.

FIG. 12D illustrates a cross-sectional view taken along line 12B-12B of FIG. 12A including a cover layer according to yet another embodiment.

FIG. 13A illustrates a top plan view of a combination cell including a photodiode and a second sensor.

FIG. 13B illustrates a cross-sectional view taken along line 13B-13B of FIG. 13A including a cover layer according to an embodiment.

FIG. 13C illustrates a cross-sectional view taken along line 13B-13B of FIG. 13A including a cover layer according to another embodiment.

FIG. 13D illustrates a cross-sectional view taken along line 13B-13B of FIG. 13A including a cover layer according to yet another embodiment.

FIG. 14 illustrates a conceptual block diagram of a combination photodiode and Hall Effect sensor cell.

FIG. 15 illustrates a block diagram of a multiple sensor-types sensor and signal conditioner.

FIG. 16A illustrates a combination magnetic/light sensor cell formed on a common semiconductor die.

FIG. 16B illustrates a combination photodiode dark and magnetic block and an optical sensor block formed on a common semiconductor die.

FIG. 16C illustrates an optical sensor block, a photodiode dark block and a magnetic block formed on a common semiconductor die.

FIG. 17 illustrates the use of a multiple sensor-types integrated circuit device in a flip phone or notebook computer.

FIG. 18 illustrates the use of a multiple sensor-types integrated circuit device as part of a window shade control or other apparatus with relatively sliding members.

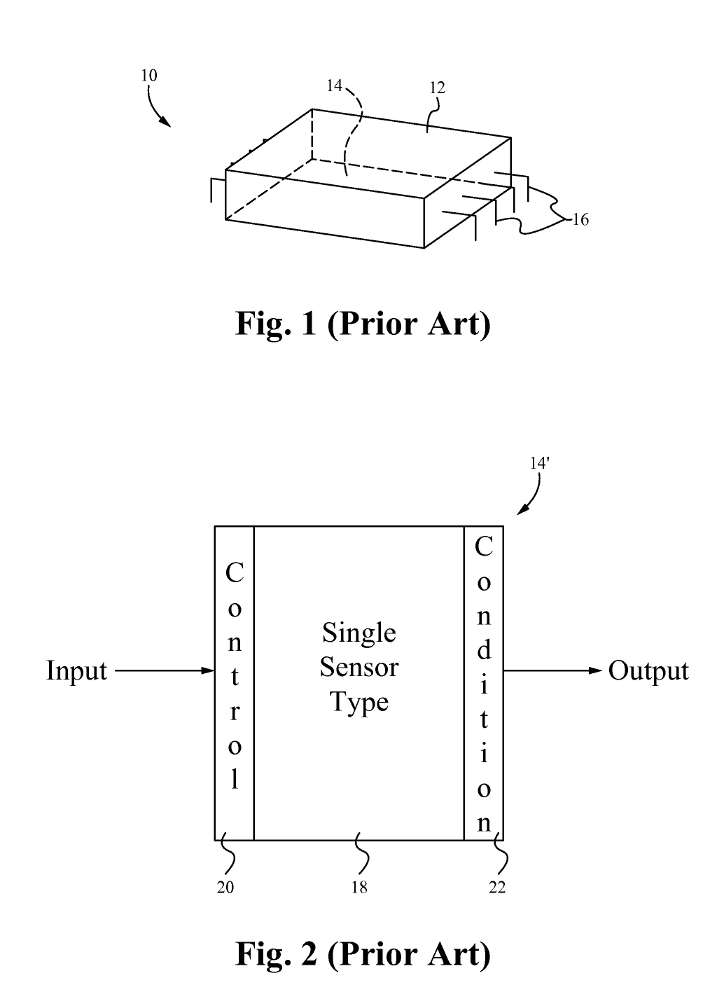

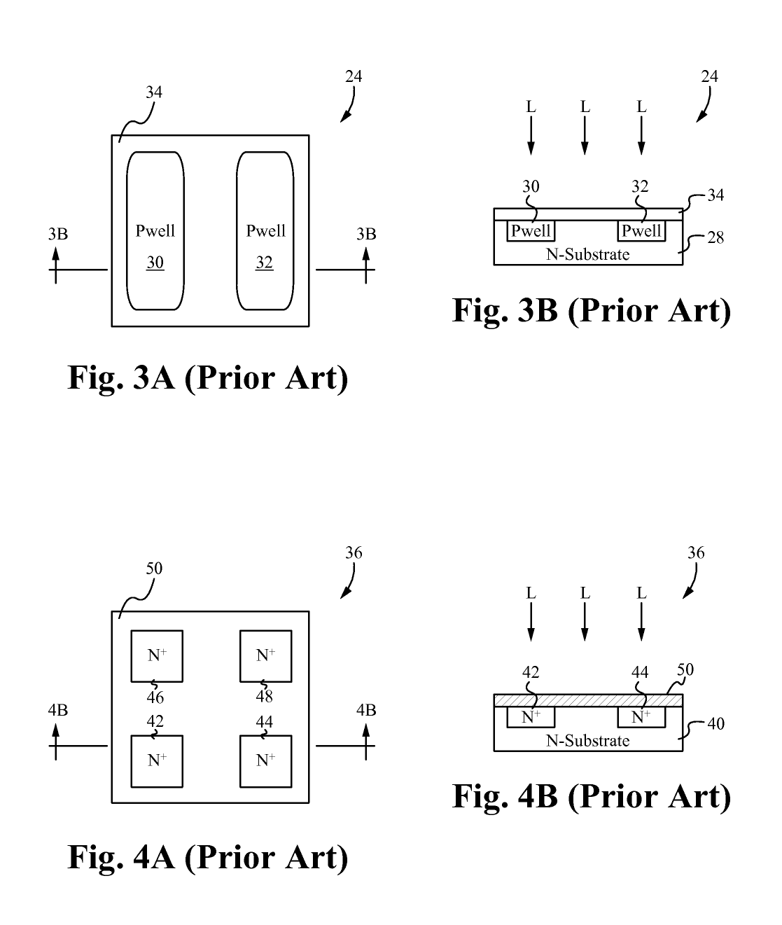

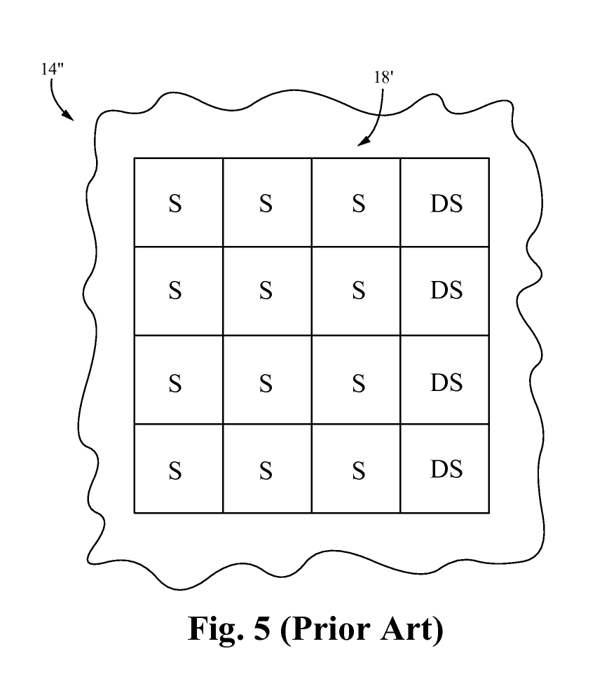

### DETAILED DESCRIPTION OF THE EMBODIMENTS

Embodiments of the present application are directed to a multiple sensor-types integrated circuit device. Those of ordinary skill in the art will realize that the following detailed description of the multiple sensor-types integrated circuit device is illustrative only and is not intended to be in any way limiting. Other embodiments of the multiple sensor-types integrated circuit device will readily suggest themselves to such skilled persons having the benefit of this disclosure.

Reference will now be made in detail to implementations of the multiple sensor-types integrated circuit device as illustrated in the accompanying drawings. The same reference indicators will be used throughout the drawings and the following detailed description to refer to the same or like parts. In the interest of clarity, not all of the routine features of the implementations described herein are shown and described. It will, of course, be appreciated that in the development of any such actual implementation, numerous implementation-specific decisions will likely be made in order to achieve the developer's specific goals, such as compliance with application and business related constraints, and that these specific goals can vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

Embodiments of a multiple sensor-types integrated circuit device includes a first sensor type and a second sensor type formed on a single semiconductor die. In some embodiments, the first sensor type is an optical sensor and the second sensor type is a magnetic sensor. By way of a non-limiting example, the optical sensor can be a photodiode and the magnetic sensor can be a Hall Effect magnetic sensor. The multiple sensor-types integrated circuit device utilizes the common structure of the optical sensor and the magnetic sensor to form the single semiconductor die that performs both optical and magnetic sensing. In other embodiments, the sensor types formed on the single semiconductor die can be of types other than, or in addition to, optical and magnetic. Integrating multiple sensing types in a single cell or die can result in a total size reduction compared to conventional separate components.

As used herein, “magnetic” shall mean a semiconductor sensor configuration which can be used to create an electrical signal by detecting a magnetic field. Also as used herein, “optical” shall mean a semiconductor sensor configuration which can be used to produce an electrical signal by detecting light (as defined above). Therefore a “light sensor” and an “optical sensor” are, at times, used synonymously. However, at other times “optical sensors” may refer to more complex forms of light detection, including multiple cell light detectors, or to the addition of other optical components such as filters, lenses, etc.

The multiple sensor-types integrated circuit device includes a plurality of sensing cells. The plurality of sensing cells form a sensing block. In some embodiments, each sensing cell includes at least the first sensing type and the second sensing type. In other embodiments, each sensing cell includes only one of the sensing types, and the different cells with the different sensing types are patterned within the sensing block, such as in an alternating pattern of an optical sensing cell positioned next to a magnetic sensing cell, which is turn is positioned next to another optical sensing cell, and so on throughout the sensing block. Patterns other than an alternating pattern can be used.

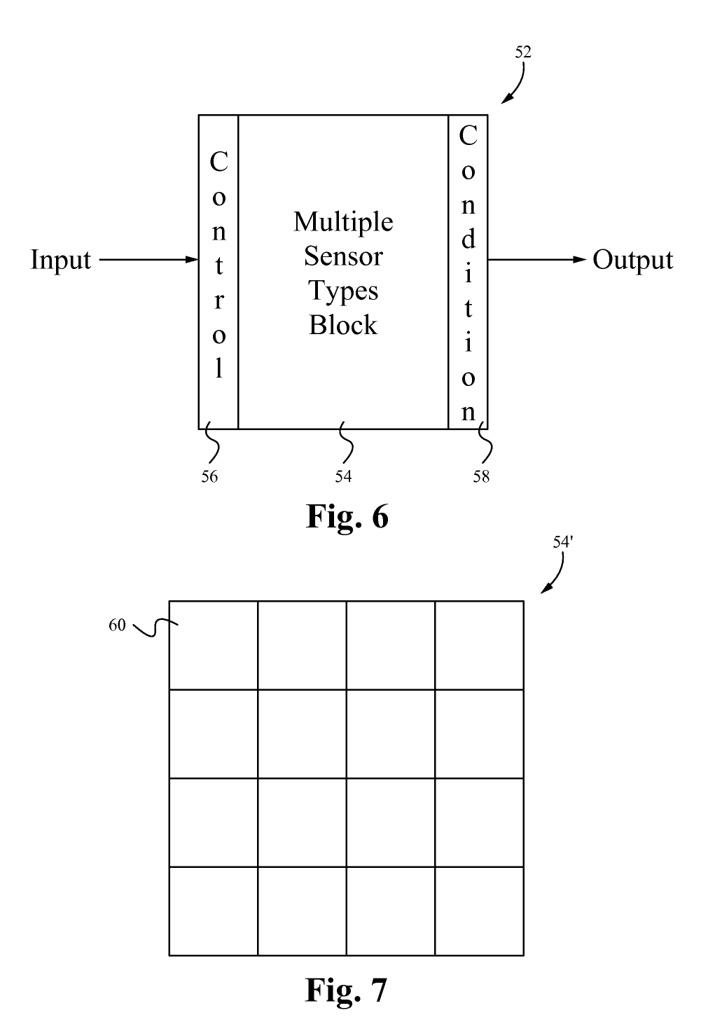

FIG. 6 illustrates, by way of example and not limitation, a multiple sensor-types die 52 including a multiple sensor-types block 54, a control block 56 and a conditioning block 58. Block 54 includes a plurality of sensor cells. In some embodiments, each sensor cell is configured having a single sensor type, for example a light sensor, a magnetic sensor, a temperature sensor, etc. In other embodiments, each sensor cell is configured having two or more sensor types. For the purpose of examples set forth herein, the sensor types are generally referred to in terms of two sensor types: a light sensor and a magnetic sensor. It is to be understood, however, that different or additional sensor types can also be employed. Furthermore, for the purpose of examples set forth herein, a light sensor is described as one or more photodiode cells and a magnetic sensor is described as one or more Hall Effect cells. It is to be understood, however, that different light and magnetic sensor types can also be employed.

The control block 56 can operate much as described with respect to the prior art and may include additional functionality. For example, the control block 56 can enable or disable sensor types, reconfigure the sensor cells through the use of switches, etc. Likewise, the conditioning block 58 can operate much as described with respect to the prior art and may include additional functionality as described subsequently.

FIG. 7 illustrates, by way of non-limiting example, a multiple sensor-types block 54′ which forms at least a part of multiple sensor-types block 54 in FIG. 6. In this embodiment, two or more sensor cells 60 of different types are formed within block 54′ on integrated circuit die 52. Various embodiments, set forth by way of example and not limitation, will be described subsequently.

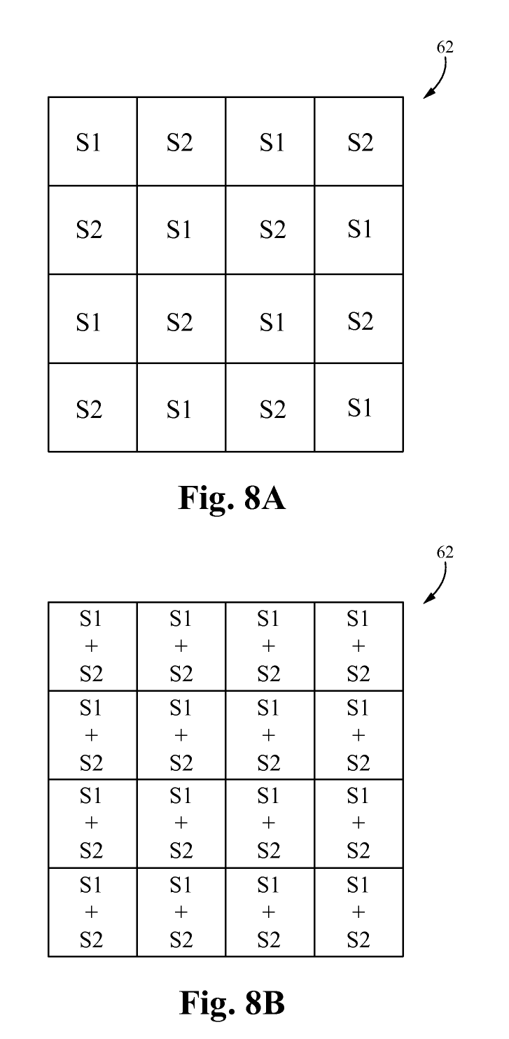

FIG. 8A illustrates, by way of non-limiting example, a multiple sensor-types block 62 having sensor cells of a first sensor cell type S1 and a second sensor cell type S2. In this embodiment, each sensor cell is configured having only a single sensor-type. In the example shown in FIG. 8A, the sensor cells S1 and S2 are laid out in a checkerboard pattern, but other patterns are also contemplated. Furthermore, the ratio of S1/S2 sensor cells may be varied, and additional sensor cell types, for example sensor cell types S3, S4, . . . , SN etc., may be added.

In other embodiments, each sensor cell within the multiple sensor-types block, such as each cell 60 in the block 54′ of FIG. 7, is configured as having multiple sensor-types, such as each cell having a light sensor and a magnetic sensor. FIG. 8B illustrates, by way of non-limiting example, a multiple sensor-types block 62′ having sensor cells of multiple sensor-types, such as the first sensor cell type S1 and the second sensor cell type S2. In this embodiment, each sensor cell is configured having both sensor-types S1 and S2.

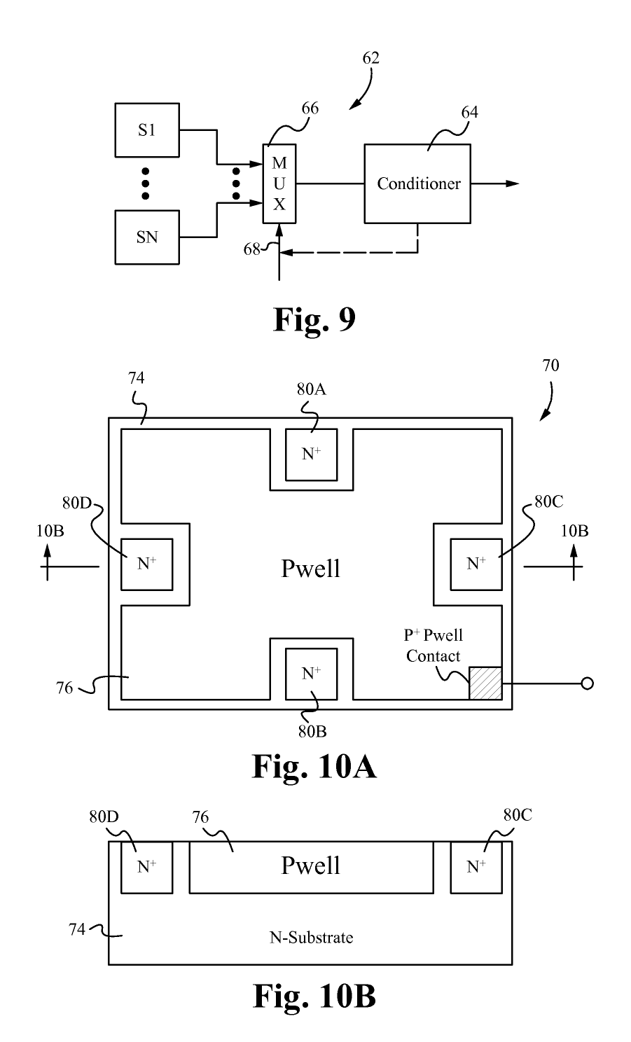

FIG. 9 is a block diagram of a plurality of sensor cell types S1, . . . , SN having outputs coupled to a conditioner block 64 by a multiplexer (MUX) 66. The block S1 in FIG. 9 represents the sensed signals sent from each of the sensor cells types S1 in the multiple sensor-types block, such as the sensed signals output from each of the sensor cell types S1 in FIG. 8. The MUX 66 is controlled by a control input 68. By way of non-limiting example, the control input 68 is supplied by the conditioner block 64. In another non-limiting example, the control signal is supplied from off-chip. In this way, the circuitry of the conditioner block can be used for multiple sensor-types, saving chip “real estate” and potentially lowering costs.

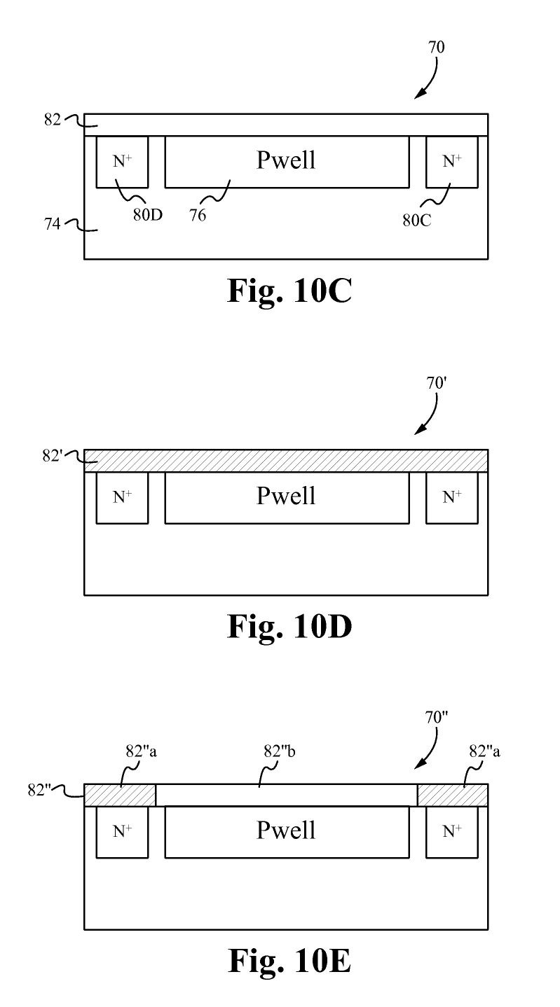

FIGS. 10A and 10B illustrate, by way of example and not limitation, a first combination photodiode and Hall Effect sensor cell 70. FIG. 10A is a top plan view of the cell 70 and FIG. 10B is a cross-section taken along line 10B-10B of FIG. 10A. The cell 70 includes an N-substrate 74, a Pwell 76, and a plurality of N+ regions 80a, 80b, 80c and 80d. The N-substrate is typically silicon (e.g., an N-doped monocrystalline silicon wafer), although other semiconductor materials can be used as will be appreciated by those of skill in the art. Although only the N-substrate is shown in FIG. 10B, the substrate of the semiconductor die within which the cell 70 is formed can be comprised of one or more additional substrate layers. For example, the N-substrate 74 may be an N-EPI layer formed within a P-substrate. Also, it should be noted that the polarities recited herein may be reversed, such that N-doped material can be P-doped and vice versa.

In operation, the cell 70 functions as a light sensor by measuring the current generated as a resulting of light impinging the Pwell 76. The amount of measured current is proportional to the amount of light impinging the Pwell. The cell 70 functions as a Hall Effect magnetic sensor by flowing current through two of the N+ regions, such a supplying current to the N+ region 80a and grounding the N+ region 80b and measuring the differential voltage across the other two N+ regions, such as N+ regions 80c and 80d. The differential voltage varies in the presence of a magnetic field. To minimize errors in the differential voltage readings, different phases are measured and commutatively processed, where each phase corresponds to apply current to a different N+ region and measuring the differential voltage across a corresponding pair of N+ regions. For example, a first phase is as described above, a second phase applies current to the N=region 80c, grounds the N+ region 80d, and measures the differential voltage across the N+ regions 80a and 80b, and so on as to apply current to each N+ region.

FIG. 10C illustrates the cell 70 including a cover layer 82 according to an embodiment. In the embodiment shown in FIG. 10C, the cover layer 82 is translucent. FIG. 10D illustrates the cell 70′ including a cover layer 82′ according to another embodiment. In the embodiment shown in FIG. 10D, the cover layer 82′ is opaque. As used herein “translucent” shall mean that light, as previously defined, is permitted to pass through the cover layer without undue attenuation. Therefore, “translucent”, as defined herein, includes transparent. A variety of inorganic and organic materials may be used for the cover layer, as will be appreciated by those of skill in the art. The translucent cover layer may selectively filter one or more ranges of wavelengths of the impinging light for the reasons set forth previously. Also, as used herein, “opaque” shall mean that light is substantially blocked from passing through the cover layer. A cover layer may still be considered as being opaque even if a certain amount of light passes through to underlying layers if the amount of light transmitted through the cover layer does not affect the operation of the layers below. Opaque layers may be conveniently be made of metal, such as aluminum, although other materials are suitable as will be appreciated by those of skill in the art.

FIG. 10E illustrates the cell 70″ including a cover layer 82″ according to yet another embodiment. In the embodiment shown in FIG. 10E, a portion 82″a of the cover layer 82″ over the Pwell 76 is translucent and a portion 82″b over the N+ regions 80a, 80b, 80c, and 80d is opaque. The portions 82″a may selectively filter one or more ranges of wavelengths of the impinging light for the reasons set forth previously.

Implementation of one of the cover layers 82, 82′, and 82″ is application specific. In order for the cell to function as a light sensor, the Pwell 76 must be exposed to light, which requires a translucent cover layer as in FIGS. 10C and 10E. In some applications, the light sensor results can be improved by compensating for “dark current” in the photodiode, where the dark current is a measure of leakage current, noise, and random fluctuations in the photodiode. The dark current can be determined by using an opaque cover layer, as in FIG. 10D, over the Pwell 76 and measuring the corresponding current of the photodiode. In this manner, the cell 70′ in FIG. 10D functions as a dark cell. In some embodiments, one or more cells in a sensor block can include an opaque cover layer to determine the dark current, which can then be used to compensate the light sensor signals obtained from those cells having a translucent cover layer.

The cell can function as a Hall Effect magnetic sensor having either a translucent cover layer, as in FIG. 10C, an opaque cover layer, as in FIG. 10D, or combination opaque and translucent cover layer, as in FIG. 10E. Hall Effect sensors may be negatively effected when exposed to light. In some applications, the effects of impinging light are negligible or can be compensated for, which enables the use of the translucent cover layer. In this case, the light effects on a Hall Effect cell can be previously determined, and the control block and the conditioning block can be configured to compensate for the previously determined light effect. In other applications, the light effect on a Hall Effect sensor is too great which requires the use of the opaque cover layer. In those embodiments where one or more cells in a sensor block include an opaque cover layer, such as in FIG. 10D, the one or more dark cells can function to both determine a dark current measurement and function as a Hall Effect sensor that is not exposed to light. As opposed to, or in addition to, having some cells entirely covered with a translucent cover layer and one or more cells entirely covered with an opaque layer, one some or all of the cells can be configured having the combination opaque and translucent cover layer, such as in FIG. 10E. In general, a sensor block having a plurality of cells can be configured such that the plurality of cells are configured having any combination of cover layers, such as the translucent cover layer 82 in FIG. 10C, the opaque cover layer 82′ in FIG. 10D, and the combination cover layer 82″ in FIG. 10E.

In the exemplary configuration shown in FIG. 10A, the cell 70 includes one Pwell and four N+ regions. In alternative configurations, the cell can include more than one Pwell and more than four N+ regions. The relative number, size and positions of the Pwell and N+ regions shown in FIG. 10A is for exemplary purposes only and is not limiting of the possible numbers, sizes, and positions of Pwells and N+ regions.

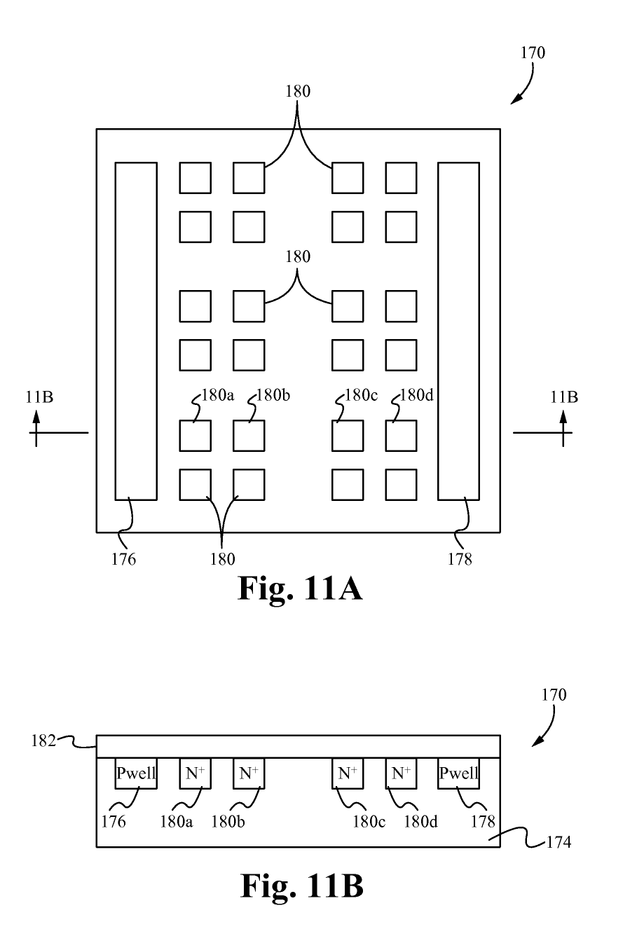

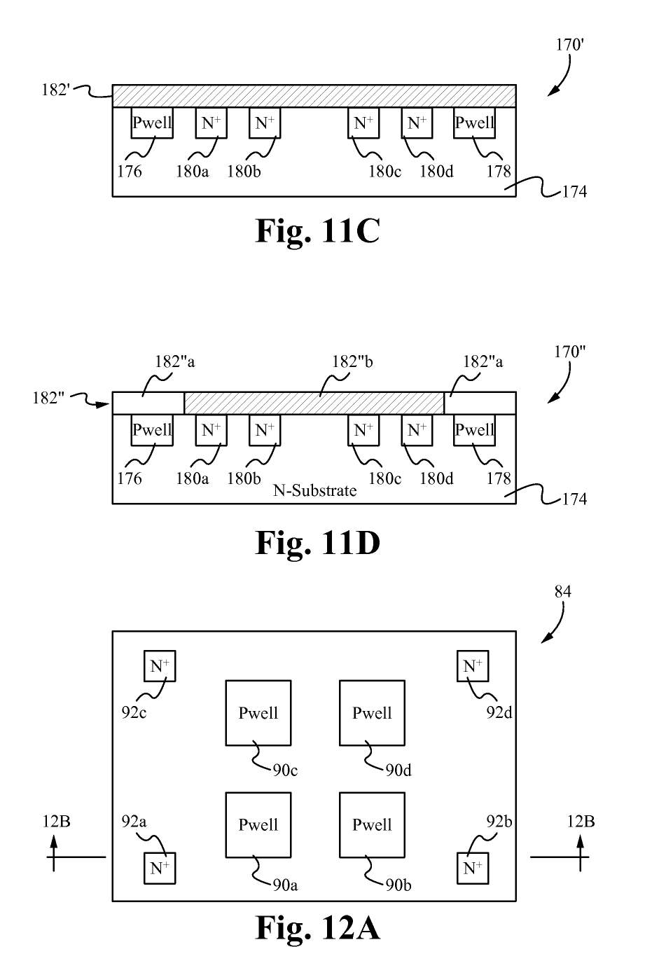

FIGS. 11A and 11B illustrate, by way of example and not limitation, a second combination photodiode and Hall Effect sensor cell 170 according to an embodiment. FIG. 11A is a top plan view of the cell 170 and FIG. 11B is a cross-section taken along line 11B-11B of FIG. 11A. The cell 170 includes an N-substrate 174, a Pwell 176, a Pwell 178, a plurality of N+ regions 180 including N+ regions 180a, 180b, 180c and 180d, and a cover layer 182. The N-substrate is typically silicon (e.g., an N-doped monocrystalline silicon wafer), although other semiconductor materials can be used as will be appreciated by those of skill in the art. Although only the N-substrate is shown in FIG. 11B, the substrate of the semiconductor die within which the cell 170 is formed can be comprised of one or more additional substrate layers. For example, the N-substrate 174 may be an N-EPI layer formed within a P-substrate. Also, it should be noted that the polarities recited herein may be reversed, such that N-doped material can be P-doped and vice versa. An advantage of a multiple Pwell configuration is cover each Pwell with a different light filter to provide a specific photo response.

In the embodiment shown in FIG. 11B, the cover layer 182 is a translucent cover layer. FIG. 11C illustrates the cell 170′ including a cover layer 182′ according to another embodiment. In the embodiment shown in FIG. 11C, the cover layer 182′ is opaque. FIG. 11D illustrates the cell 170″ including a cover layer 182″ according to yet another embodiment. In the embodiment shown in FIG. 11D, a portion 182″a of the cover layer 182″ over the Pwell 176 is translucent and a portion 182″b over the N+ regions 180, including N+ regions 180a, 180b, 180c, and 180d, is opaque.

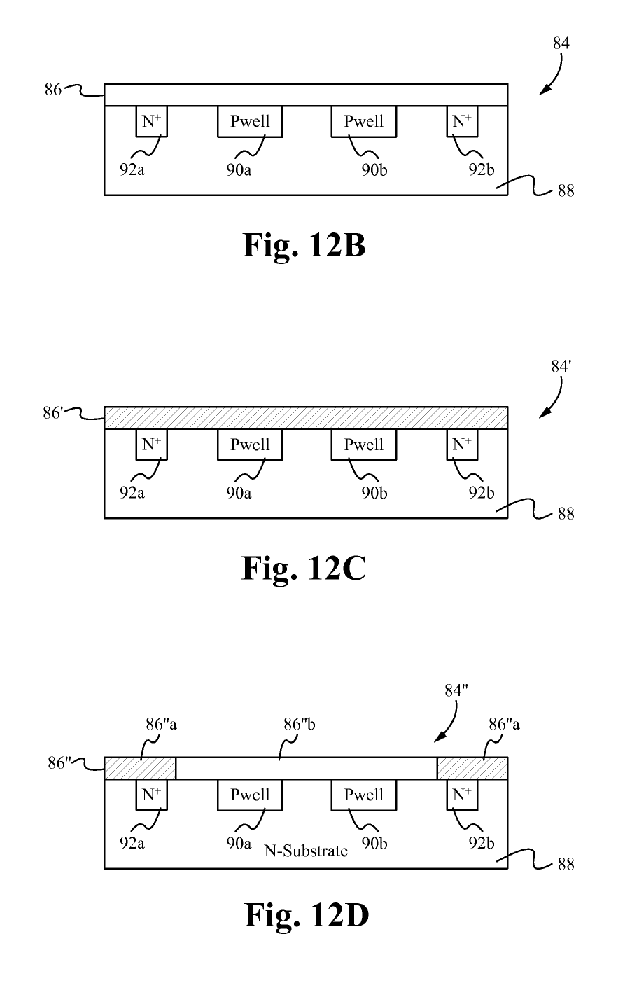

FIGS. 12A and 12B illustrate, by way of example and not limitation, a third combination photodiode and Hall Effect sensor cell 84. FIG. 12A is a top plan view of the cell 84 and FIG. 12B is a cross-section taken along line 12B-12B of FIG. 12A. The cell 84 includes an N-substrate 88, four P wells 90a, 90b, 90c and 90d, a four N+ regions 92a, 92b, 92c and 92d, and a cover layer 86. The N-substrate is typically silicon although other semiconductor materials can be used as will be appreciated by those of skill in the art. The polarities recited herein may be reversed, such that N-doped material can be P-doped and vice versa.

In the embodiment shown in FIG. 12B, the cover layer 86 is a translucent cover layer. FIG. 12C illustrates the cell 84′ including a cover layer 86′ according to another embodiment. In the embodiment shown in FIG. 12C, the cover layer 86′ is opaque. FIG. 12D illustrates the cell 84″ including a cover layer 86″ according to yet another embodiment. In the embodiment shown in FIG. 12D, a portion 86″b of the cover layer 86″ over the Pwells 90a and 90b is translucent and a portion 86″a over the N+ regions 92, including N+ regions 90a, 90b, 90c, and 90d, is opaque.

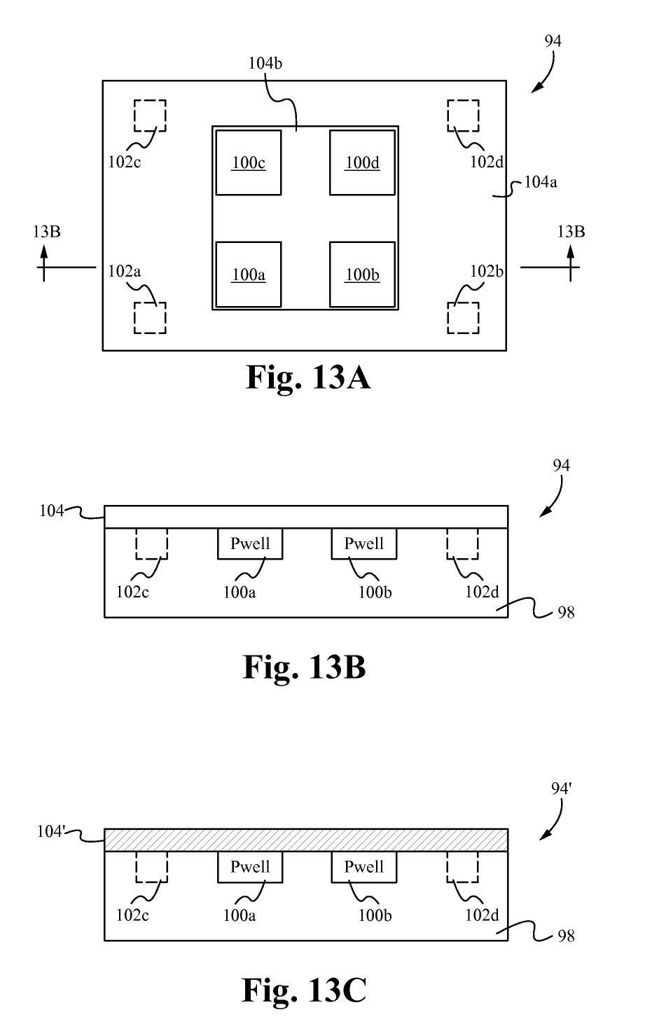

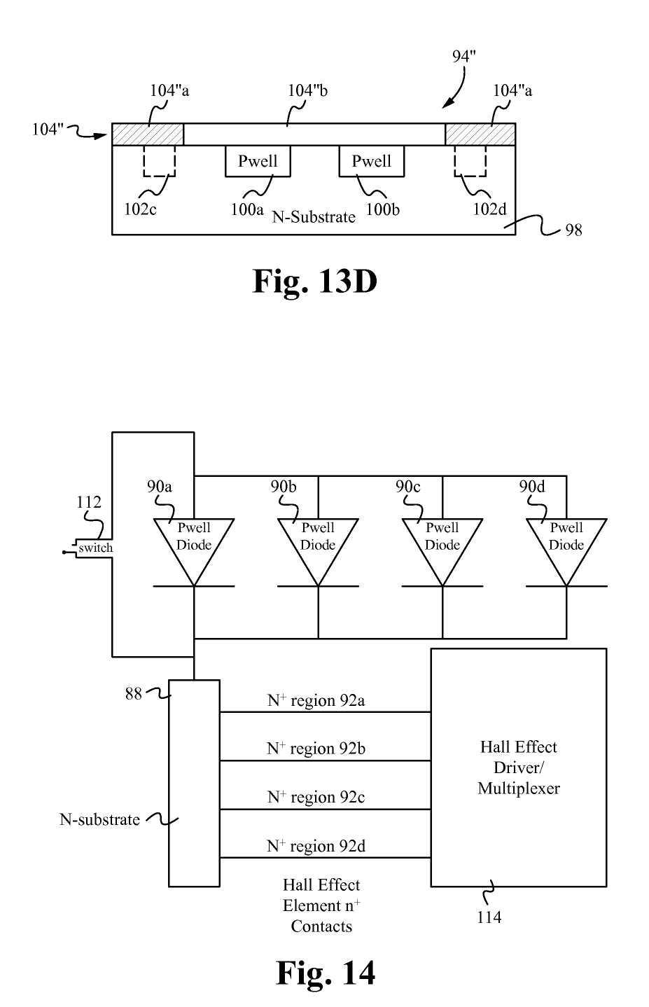

FIGS. 13A and 13B illustrate, by way of example and not limitation, a combination photodiode and additional sensor(s) cell 94. FIG. 13A is a top plan view of the cell 94 and FIG. 13B is a cross-section taken along line 13B-13B of FIG. 13A. The cell 94 includes an N-substrate 98, four Pwells 100a, 100b, 100c and 100d, a cover layer 104, and four additional sensor regions 102a, 102b, 102c and 102d. The N-substrate is typically silicon (e.g., an N-doped monocrystalline silicon wafer), although other semiconductor materials can be used as will be appreciated by those of skill in the art. The polarities recited herein may be reversed, such that N-doped material can be P-doped and vice versa.

In the embodiment shown in FIG. 13B, the cover layer 104 is a translucent cover layer. FIG. 13C illustrates the cell 94′ including a cover layer 104′ according to another embodiment. In the embodiment shown in FIG. 13C, the cover layer 104′ is opaque. FIG. 13D illustrates the cell 94″ including a cover layer 110″ according to yet another embodiment. In the embodiment shown in FIG. 13D, a portion 104″b of the cover layer 104″ over the Pwells is translucent and a portion 104″a over the regions 102, including regions 102a, 102b, 102c, and 102d, is opaque.

The additional sensor(s) 102a, 102b, 102c, 102d can be the same as each other or can be different from each other. For example, the additional sensors 102a, 102b, 102c, 102d may be Hall Effect sensor cells. By way of further example, the additional sensors 102a, 102b, 102c, 102d may be combination sensor cells such as the combination sensor cell 70, 170, and 84. In this second example, the photodiodes of the cells 70, 170, and 84 can serve as “dark” photodiodes for the purposes set forth above if the portion 104″a is opaque.

Each of the cells described above includes a cover layer. Alternatively, the cells can be configured without a cover layer.

FIG. 14 illustrates a conceptual block diagram of a combination photodiode and Hall Effect sensor cell which is conveniently referenced with respect to FIGS. 12A and 12B by way of a non-limiting example. The photodiode portion of the cell 84 in FIG. 12A includes the Pwells 90a, 90b, 90c, 90d which are functionally represented as Pwell diodes in FIG. 14. A control block is implemented in part using a bypass switch 112 by way of example. The Pwell diodes 90a, 90b, 90c, 90d are each coupled to the N-substrate 88. The N+ regions 92a, 92b, 92c, 92d are coupled to a Hall Effect Driver/Multiplexer 114. The operation of Hall Effect magnetic sensors and the construction and use of Hall Effect drivers are well known to those of skill in the art. In operation, optical sensing using the Pwells does not occur concurrently as magnetic sensing using the N+ regions. The cell 84 functions as a Hall Effect magnetic sensor by closing the switch 112, thereby forming a short across the Pwells 90a, 90b, 90c, 90d and rending the photodiodes inoperable. To resume photo-detection, the switch 112 is opened.

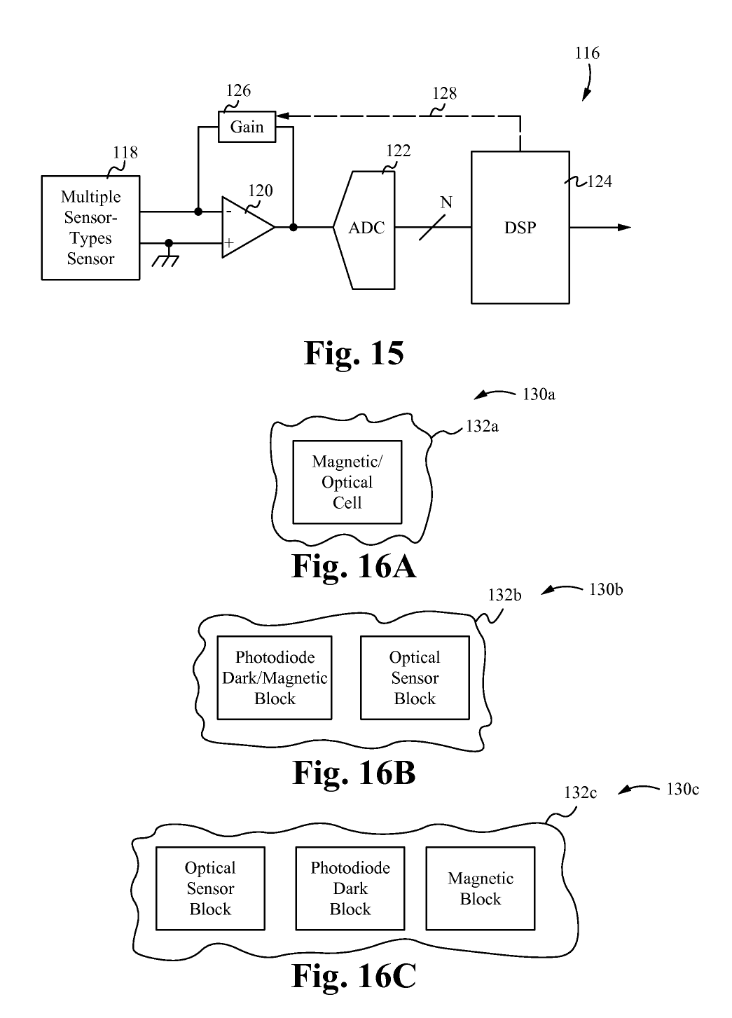

In some embodiments, the sensed signals corresponding to both the optical sensor and the magnetic sensor of a cell can be processed used a common conditioner circuit. FIG. 15 illustrates a block diagram of a circuit 116 including a multiple sensors-type sensor, such as the multiple sensor-types block 54 in FIG. 6, and a signal conditioner set forth by way of non-limiting example. A signal conditioner can include, but is not limited to, a differential amplifier 120, an analog-to-digital converter (ADC) 122, a digital signal processor (DSP) 124, and a gain circuit 126. The multiple sensors-type sensor 118 is coupled to the differential amplifier 120, in this non-limiting example. An output of the amplifier 120 is input into the ADC 122 having an N bit output. The optional DSP 124 can further condition the signal. The gain control circuit 126 is, in this example, coupled between the output of the amplifier 120 and one of its inputs. The DSP 124 may provide a control signal on a line 128 to the gain circuit 126. The signal conditioner is configured to process two different signals, the optical related signal and the magnetic related signal. It is understood that alternative signal processing circuits can be used to process the optical related signals and the magnetic related signals output from the multiple sensor-types sensor. For example, an alternative conditioner circuit including additional or different circuit components than those shown in FIG. 15 can be used to commonly process the optical related signals and the magnetic related signals. As another example, separate processing circuits can be used to process the optical related signals and the magnetic related signals.

FIGS. 16A-16C illustrate various combinations of elements to provide a multiple sensor-types integrated circuit device. In FIG. 16A, a multiple sensor-types integrated circuit device 130A includes a semiconductor die 132a having a combination magnetic/optical cell. In FIG. 16B, a multiple sensor-types integrated circuit device 130B includes a semiconductor die 132b having a combination photodiode dark/magnetic block and an optical sensor block. In FIG. 16C, a multiple sensor-types integrated circuit device 130C includes a semiconductor die 132C having an optical sensor block, a photodiode dark block, and a magnetic block. Other combinations are also contemplated. The configurations shown in FIGS. 16A-16C are directed to different combination on the block level. Similar configurations can be applied at the cell level within the blocks.

The embodiments described above are directed to multiple sensor-types cells where the sensing elements of the different sensor-types are essentially co-planar. For example, the Pwells used for optical sensing and the N+ regions used for magnetic sensing are positioned at a top surface of the substrate. In alternative embodiments, the optical sensing elements and the magnetic sensing elements do not have to be co-planar. For example, the optical sensing elements can stacked above the magnetic sensing elements since magnetic fields to be detected penetrate below a surface of the substrate.

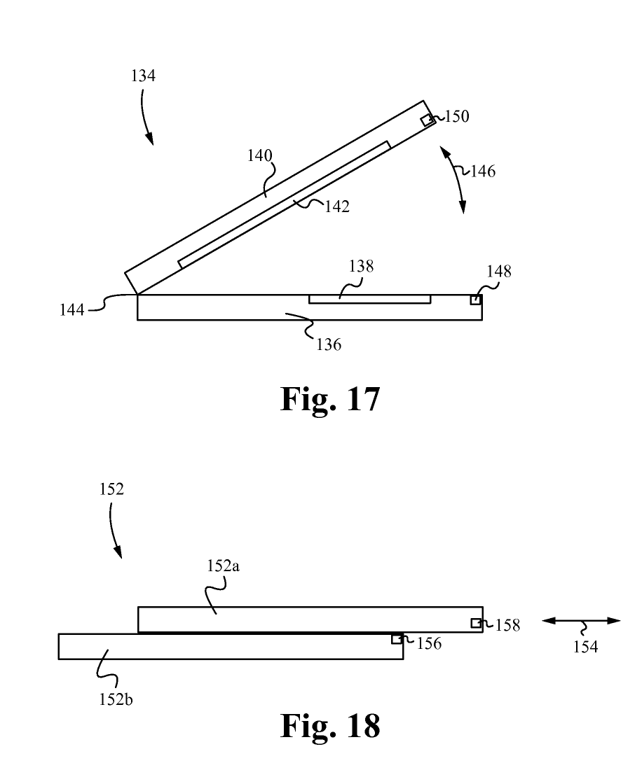

FIG. 17 illustrates the use of a multiple sensor-types integrated circuit device in a “flip-phone” or notebook computer 134 by way of non-limiting example. The flip-phone or notebook computer 134 includes a base portion 136 having a keyboard 138 and a top portion 140 having a screen 142. The base portion 136 and top portion 140 are connected by a hinge 144 for relative motion as indicated at 146. A magnet 148 is provided in the base portion 136 and a magnetic/optical multiple sensor-types integrated circuit device 150 is provided in top portion 140. The multiple sensor-types integrated circuit device 150 can therefore serve as an ambient light sensor (ALS) to, for example, control the backlighting of screen 142, and to detect when the notebook computer is closed (by sensing the magnetic field of the magnet 148).

FIG. 18 illustrates the use of a multiple sensor-types integrated circuit device as part of a window shade control 152 which detects both ambient light and position of the window shade by way of further non-limiting example. Window shade control 152 includes a first portion 152a which moves in relation to a second portion 152b as indicated at 154. A magnet 156 is provided in portion 152b and a magnet/optical multiple sensor-types integrated circuit device 158 is provided in portion 152a. The window shade control can then adjust the position of the window shade based upon ambient light and relative positions of the shade portions. This arrangement also works well for other apparatus having mutually sliding members, such as some cell phones.

The present application has been described in terms of specific embodiments incorporating details to facilitate the understanding of the principles of construction and operation of the multiple sensor-types integrated circuit device. Many of the components shown and described in the various figures can be interchanged to achieve the results necessary, and this description should be read to encompass such interchange as well. As such, references herein to specific embodiments and details thereof are not intended to limit the scope of the claims appended hereto. It will be apparent to those skilled in the art that modifications can be made to the embodiments chosen for illustration without departing from the spirit and scope of the application.

What is claimed:

1. A multiple sensor-type integrated circuit device comprising:
a. a semiconductor die including a first sensor type and a second sensor type formed thereon;
b. an electrically insulating package enclosing said semiconductor die; and
c. a plurality of electrically conductive leads coupled to said semiconductor die and extending from said package.

2. The device of claim 1 wherein the first sensor type is an optical sensor and the second sensor type is a magnetic sensor.

3. The device of claim 2 wherein the semiconductor die comprises a block, further wherein the block comprises a plurality of cells.

4. The device of claim 3 wherein each cell comprises only of the optical sensor or the magnetic sensor.

5. The device of claim 3 wherein each cell comprises a multiple sensor-type sensor including the optical sensor and the magnetic sensor.

6. The device of claim 5 where each cell further comprises a translucent cover layer.

7. The device of claim 6 further comprising control circuitry coupled to the block, wherein the control circuitry comprises a processing algorithm configured to compensate for the effect of light impinging the magnetic sensor.

8. The device of claim 5 wherein each cell further comprises a cover layer, wherein the cover layer for at least one of the cells is opaque, and the covering layer for the remaining cells is translucent.

9. The device of claim 8 wherein a magnetic sensor signal from the at least one cell having the opaque cover layer is processed to determine a presence of a magnetic field.

10. The device of claim 8 wherein the optical sensor in the at least one cell having the opaque cover layer is used to measure a dark current of the optical sensor.

11. The device of claim 5 wherein each cell comprises a cover layer, wherein the cover layer includes an opaque portion positioned over the magnetic sensor and a translucent portion positioned over the optical sensor.

12. The device of claim 1 wherein the first sensor type and the second sensor type are formed in a cell.

13. The device of claim 1 wherein the first sensor type and the second sensor type are formed in a block comprising a plurality of cells.

14. The device of claim 13 wherein the block is a first block and further comprising a second block of the first sensor type.

15. The device of claim 1 wherein the first sensor type is formed in a first block and in a second block and wherein the second sensor type is formed in a third block.

16. The device of claim 1 further comprising a conditioning block formed on the semiconductor die.

17. The device of claim 16 wherein both the first sensor type and the second sensor type are coupled to the conditioning block.

18. The device of claim 17 wherein the first sensor type and the second sensor type are coupled to the conditioning block by a multiplexer.

19. The device of claim 16 wherein the conditioning block is a first conditioning block associated with the first sensor and further comprising a second conditioning block associated with the second sensor.

20. The device of claim 16 wherein the conditioning block comprises an amplifier circuit having an input coupled to at least one of the first sensor type and the second sensor type.

21. The device of claim 20 wherein the conditioning block further comprises an analog-to-digital converter (ADC) having an input coupled to an output of the amplifier circuit.

22. The device of claim 21 wherein the conditioning block further comprises a digital signal processor (DSP) having an input coupled to an output of the ADC.

23. The device of claim 22 wherein the conditioning block further comprises a gain control coupled between an input and an output of the amplifier.

24. The device of claim 23 wherein a control input of the gain control is coupled to the DSP.

25. The device of claim 1 further comprising control circuitry coupled to at least one of the first sensor type and the second sensor type.

26. The device of claim 1 wherein the integrated circuit device forms a part of an electronic device selected from the group consisting essentially of computers, telephones and hand-held electronic devices.

27. A multiple sensor-type integrated circuit die comprising:
a. a semiconductor substrate of a first polarity;
b. a plurality of regions of the first polarity formed in the substrate, the plurality of regions being relatively more heavily doped than the substrate, wherein the plurality of regions comprise a first sensor type;
c. a plurality of wells of a second polarity formed in the substrate, wherein the plurality of wells comprise a second sensor type different than the first sensor type; and
d. a cover layer formed over the substrate.

28. The die of claim 27 wherein the semiconductor substrate is an N-substrate, the plurality of regions are N+ regions, and the plurality of wells are P wells.

29. The die of claim 28 wherein the cover layer over the P wells is of a first type and the cover layer over the N+ regions is of a second type.

30. The die of claim 29 wherein the cover layer of the first type is non-metallic and the cover layer of the second type is metallic.

31. The die of claim 29 wherein the cover layer of the first type is translucent and the cover layer of the second type is opaque.

32. A multiple sensor-type integrated circuit die comprising:
a. a multiple sensor-type sensor block including a first type of sensor and a second type of sensor; and
b. a conditioning block coupled to the multiple sensor-type sensor block to process a first sensor signal corresponding to the first type of sensor and a second signal corresponding to the second type of sensor.

33. The die of claim 32 wherein the first type of sensor comprises an optical sensor and the second type of sensor comprises a magnetic sensor, further wherein the conditioning block is configured to process both optical signals and magnetic signals sensed by the multiple sensor-type sensor block.

34. The die of claim 32 further comprising a multiplexer coupled between the multiple sensor-type sensor block and the conditioning block.

35. The die of claim 32 wherein the conditioning block comprises an amplifier circuit having an input coupled to at least one of the first sensor type and the second sensor type.

36. The die of claim 35 wherein the conditioning block further comprises an analog-to-digital converter (ADC) having an input coupled to an output of the amplifier circuit.

37. The die of claim 36 wherein the conditioning block further comprises a digital signal processor (DSP) having an input coupled to an output of the ADC.

38. The die of claim 37 wherein the conditioning block further comprises a gain control coupled between an input and an output of the amplifier.

39. The die of claim 38 wherein a control input of the gain control is coupled to the DSP.

40. The die of claim 32 further comprising control circuitry coupled to at least one of the first sensor type and the second sensor type.
